(19) United States
(12) Patent Application Publication
(10) Pub. No.: US 2005/0287297 A1
(43) Pub. Date: Dec. 29, 2005

(54) Apparatus and methods of making nanostructures by inductive heating

(75) Inventors: Alexandru Radu Biris, Cluj Napoca (RO); Dan Lupu, Cluj Napoca (RO); Alexandru Sorin Biris, Little Rock, AR (US); Jon Gardner Wilkes, Little Rock, AR (US); Dan Alexander Buzatu, Benton, AR (US); Dwight Wayne Miller, Whitehall, AR (US); Jerry A. Darsey, Little Rock, AR (US)

Correspondence Address: MORRIS MANNING & MARTIN LLP, 1600 ATLANTA FINANCIAL CENTER, 3343 PEACHTREE ROAD, NE, ATLANTA, GA, 30326-1044, US

(73) Assignee: Board of trustees of the University of Arkansas, Little Rock, AR (US)

(21) Appl. No.: 11/131,912

(22) Filed: May 18, 2005

Related U.S. Application Data
(60) Provisional application No. 60/571,999, filed on May 18, 2004.

(51) Int. Cl. C23C 16/00

(52) U.S. Cl. 427/248.1; 118/723 I

(57) ABSTRACT

An apparatus and methods for making nanostructures. In one embodiment, the apparatus has a process chamber having a reaction zone, a conductive susceptor with catalysts placed in the reaction zone, means for providing a time-dependent electromagnetic field in the reaction zone so as to induce a current in the conductive susceptor to generate a heat flow, and means for supplying a carbon-containing gas to the reaction zone under a set of conditions to interact with the catalysts to allow nanostructures to be formed.

### CROSS-REFERENCE TO RELATED PATENT APPLICATION

This application claims the benefit, pursuant to 35 U.S.C. §119(e), of provisional U.S. patent application Ser. No. 60/571,999, filed May 18, 5004, entitled “Apparatus and Methods of High Throughput Generation of Nanostructures By Inductive heating and Improvements Increasing Productivity while Maintaining Quality and Purity,” by Alexandru Radu Biris et al., which is incorporated herein by reference in its entirety.

Some references, if any, which may include patents, patent applications and various publications, are cited and discussed in the description of this invention. The citation and/or discussion of such references is provided merely to clarify the description of the present invention and is not an admission that any such reference is “prior art” to the invention described herein. All references, if any, cited and discussed in this specification are incorporated herein by reference in their entireties and to the same extent as if each reference was individually incorporated by reference.

### FIELD OF THE INVENTION

The present invention is generally related to the field of production of nanostructures, and, more particularly, is related to an apparatus and methods of making nanostructures by inductive heating.

### BACKGROUND OF THE INVENTION

Presently, the generation of high purity carbon nanostructures (e.g., single wall and multi-wall nanotubes and nanofibers in addition to nanomaterials from other elements) has been realized by several methods, including arc discharge, Pulsed Laser Vaporization (PLV) and Chemical Catalytic Vapor Deposition (CCVD).

In order to efficiently mass-produce highly pure nanostructures at low cost the energy consumption during the heating process may need to be minimized. The main disadvantage of using classical ovens to produce nanostructures is the resulting temperature gradient along the length of the oven. This temperature gradient results in varying temperature conditions that have a significant negative impact on the quality, characteristics, and purity of carbon nanostructures grown therein. Furthermore, conventional ovens consume large amounts of energy and heat inefficiently.

Therefore, a heretofore unaddressed need exists in the art to address the aforementioned deficiencies and inadequacies.

### SUMMARY OF THE INVENTION

The present invention provides methods and apparatus for making nanostructures using inductive heating, which increases productivity of generating nanostructures and improves the quality and purity of nanostructures. The present invention, in one aspect, relates to a nanostructures growth apparatus that has a cylindrical process chamber having a body portion defining a bore therein and a geometric central plane passing through a geometric center. The body portion is defined between a first end, and an opposite, second end of wherein the cylindrical process chamber. The cylindrical process chamber further has a first seal for sealing the first end, and an opposite, second seal for sealing the second end, respectively.

The nanostructures growth apparatus, in one embodiment, has a conductive inductor in the form of coils surrounding the body portion of the cylindrical process chamber defining a reaction zone in the bore with a longitudinal length L_{I}.

The nanostructures growth apparatus further has a conductive susceptor having a first end portion, an opposite, second end portion, and a body portion defined therebetween with a longitudinal length Lₛ. In one embodiment, the body portion defines a recess with a supporting surface for supporting catalysts, wherein the conductive susceptor is positioned in the reaction zone in the bore of the cylindrical process chamber such that the supporting surface is substantially overlapping with the geometric central plane. In operation, the conductive inductor allows an alternating current to pass through to generate an electromagnetic field with a frequency at least in the reaction zone and induce current in the conductive susceptor so as to generate a heat flow from the conductive susceptor to the body portion of the cylindrical process chamber to allow nanostructures to be grown in the bore of the cylindrical process chamber.

An inlet tube can be used for interconnecting through the first seal in fluid communication with the bore of the cylindrical process chamber, and an outlet tube can be used for interconnecting through the second seal in fluid communication with the bore of the cylindrical process chamber, respectively. At least one holder may be used for holding the cylindrical process chamber.

The cylindrical process chamber can be made of a substantially non-conductive material such as glass. In one embodiment, the cylindrical process chamber is substantially made of quartz. The cylindrical process chamber may be made of other types of materials including conductive materials.

The conductive inductor can be made from at least one of metals, alloys, and conducting polymeric materials. In one embodiment, the conductive inductor is substantially made from copper. The conductive inductor has a tube defining a channel therein for circulating a coolant. The coolant can be a gas, a liquid or a combination of both. For examples, water can be used as coolant. The conductive inductor is electrically coupled to an AC power supply. For example, a high or RF (radio frequency) frequency generator with typical parameters 1.3 MHz and 5 kW can be used as an AC power supply.

The conductive susceptor can be made of a substantially conductive material. In one embodiment, the conductive susceptor is made of a substantially conductive material that is chemically compatible to carbon and its compounds, which does not significantly affect or interfere with chemical properties of the carbon-based nanostructures. The substantially conductive material that is chemically compatible to carbon and its compounds comprises graphite, which has been used as a preferred material for the conductive susceptor to practice the present invention. Alternatively, the substantially conductive material comprises at least one of metals, alloys, and ferromagnetic materials. For examples, titanium, stainless steel, iron, molybdenum, and any of their combinations can be used to practice the present invention.

The body portion of the conductive susceptor is formed with a bottom surface, a first side surface, and a second, opposite side surface, wherein the first side surface comprises a sloped surface, and the second, opposite side surface comprises a sloped surface such that when the conductive susceptor is positioned in the reaction zone in the bore of the cylindrical process chamber, there is a space formed between the first side surface and the inner surface of the body portion of the cylindrical process chamber, and there is a space formed between the second side surface and the inner surface of the body portion of the cylindrical process chamber, respectively, for facilitating fluid communication inside the bore. Moreover, the body portion of the conductive susceptor is formed such that when the conductive susceptor is positioned in the reaction zone in the bore of the cylindrical process chamber, there is a space formed between the bottom surface and the inner surface of the body portion of the cylindrical process chamber for facilitating fluid communication inside the bore. In one embodiment, the first side surface further comprises an edge portion formed with a curvature, and the second, opposite side surface further comprises an edge portion formed with a curvature such that when the conductive susceptor is positioned in the reaction zone in the bore of the cylindrical process chamber, the edge portion of the first side surface and the edge portion of the second side surface are complimentarily in contact with and supported by corresponding parts of the inner surface of the body portion of the cylindrical process chamber, respectively. Furthermore, the bottom surface of the body portion of the conductive susceptor is formed with at least one groove for facilitating fluid communication inside the bore.

The longitudinal length L_{I} of the reaction zone and the longitudinal length Lₛ of the conductive susceptor satisfy the following relationship:
Lₛ<L_{I}.

In operation the induced current penetrates into the conductive susceptor a distance δ satisfying the following relationship:
δ=(2/ωμσ)^{1/2}
wherein ω is the angular frequency of the electromagnetic field, σ is the conductivity of the conductive susceptor, and μ is the absolute magnetic permeability of the conductive susceptor. Moreover, the induced current in the conductive susceptor generates the heat flow by absorbing the energy, P, from the electromagnetic field satisfying the following relationship:
P=Hₒ²2π(ωμ/σ)^{1/2}
with Hₒ being an amplitude of the electromagnetic field.

In another aspect, the present invention relates to a nanostructures growth apparatus that has a process chamber having a body portion defining a bore therein, a conductive inductor, and a conductive susceptor with a supporting surface for supporting catalysts and positioned in the bore of the process chamber, wherein the conductive inductor is configured and positioned in relation to the process chamber such that, in operation, the conductive inductor allows an alternating current to pass through to generate an electromagnetic field with a frequency at least in a reaction zone in the bore and induce current in the conductive susceptor so as to generate a heat flow from the conductive susceptor to the body portion of the process chamber.

In yet another aspect, the present invention relates to a nanostructures growth apparatus that has a process chamber having a body portion defining a bore therein, an electromagnetic field generating member, and a conductive susceptor with a supporting surface for supporting catalysts and positioned in the bore of the process chamber, wherein, in operation, the electromagnetic field generating member generates a time-dependent electromagnetic field in the bore and induces current in the conductive susceptor so as to generate a heat flow from the conductive susceptor to the body portion of the process chamber.

In one embodiment, the electromagnetic field generating member comprises a conductive inductor that is made from at least one of metals, alloys, and conducting polymeric materials, wherein the conductive inductor is in the form of coils surrounding the body portion of the process chamber defining a reaction zone in the bore with a longitudinal length L_{I} to allow an alternating current to pass through to generate a time-dependent electromagnetic field with a frequency. Alternatively, the electromagnetic field generating member comprises at least one electromagnetic field generator.

In a further aspect, the present invention relates to a method for making nanostructures. In one embodiment, the method comprises the steps of placing a conductive susceptor with catalysts in a reaction zone, providing a time-dependent electromagnetic field in the reaction zone so as to induce a current in the conductive susceptor to generate a heat flow, and supplying a carbon-containing gas to the reaction zone under a set of conditions to interact with the catalysts to allow nanostructures to be formed. The method may further comprise the step of purging at least the reaction zone of a nanostructure reactor with an inert gas prior to the supplying step. The method may further comprise the steps of (a) removing the conductive susceptor from the reaction zone and (b) harvesting the nanostructures after the supplying step. The time-dependent electromagnetic field has a frequency and amplitude, at least one of them can be adjusted to control the temperature of the reaction zone, which is defined by a nanostructure reactor, such as an apparatus provided according to one of the embodiment of the present invention.

In one embodiment, the method further comprises the step of forming the carbon-containing gas from a carbon source and a carrier gas, wherein the carbon source is selected from the group consisting of (a) aromatic hydrocarbons, including benzene, toluene, xylene, cumene, ethylbenzene, naphthalene, phenanthrene, anthracene or mixtures thereof; (b) non-aromatic hydrocarbons, including methane, ethane, ethylene, propane, propylene, acetylene or mixtures thereof; and (c) oxygen-containing hydrocarbons, including formaldehyde, acetaldehyde, acetone, methanol, ethanol or mixtures thereof, and combinations thereof, and wherein the carrier gas comprises one of Ar gas, hydrogen gas, Ne gas, He gas, or any combination of them.

In yet another aspect, the present invention relates to an apparatus for making nanostructures. In one embodiment, the apparatus comprises a process chamber having a reaction zone, a conductive susceptor with catalysts placed in the reaction zone, means for providing a time-dependent electromagnetic field in the reaction zone so as to induce a current in the conductive susceptor to generate a heat flow, and means for supplying a carbon-containing gas to the reaction zone under a set of conditions to interact with the catalysts to allow nanostructures to be formed. The time-dependent electromagnetic field has a frequency and amplitude, which can be adjusted by means for adjusting at least one of the frequency and the amplitude of the time-dependent electromagnetic field to control the temperature of the reaction zone. The apparatus further comprises means for forming the carbon-containing gas from a carbon source and a carrier gas.

In yet a further aspect, the present invention relates to a method for making nanostructures. In one embodiment, the method comprises the steps of placing a conductive susceptor in the reaction zone with catalysts in a reaction zone, causing skin effect at least in the conductive susceptor so as to generate a heat flow, and supplying a carbon-containing gas to the reaction zone under a set of conditions to interact with the catalysts to allow nanostructures to be formed. The method may further comprise the step of purging at least the reaction zone with an inert gas. Moreover, the method may comprise the steps of (a) removing the conductive susceptor from the reaction zone and (b) harvesting the nanostructures.

The causing step further comprises the step of causing skin effect in the catalysts to facilitate the growth of nanostructures, wherein the causing step further comprises the step of providing a time-dependent electromagnetic field in the reaction zone to cause the skin effect. An induced current penetrates into the conductive susceptor a distance δ due to the skin effect satisfying the following relationship:
δ=(2/ωμσ)^{1/2}
wherein ω is the angular frequency of the time-dependent electromagnetic field, σ is the conductivity of the conductive susceptor, and μ is the absolute magnetic permeability of the conductive susceptor, and the induced current in the conductive susceptor generates the heat flow by absorbing the energy, P, from the time-dependent electromagnetic field satisfying the following relationship:
P=Hₒ²2π(ωμ/σ)^{1/2}
wherein Hₒ is amplitude of the time-dependent electromagnetic field.

In yet another aspect, the present invention relates to an apparatus for making nanostructures. In one embodiment, the apparatus comprises a process chamber having a reaction zone, a conductive susceptor with catalysts placed in the reaction zone, means for causing skin effect at least in the conductive susceptor so as to generate a heat flow, and means for supplying a carbon-containing gas to the reaction zone under a set of conditions to interact with the catalysts to allow nanostructures to be formed, wherein the causing means comprises means for providing a time-dependent electromagnetic field in the reaction zone so as to cause skin effect.

The nanostructures as formed by practicing the present invention can be nanotubes, nanofibers, or the like.

These and other aspects of the present invention will become apparent from the following description of the preferred embodiment taken in conjunction with the following drawings, although variations and modifications therein may be affected without departing from the spirit and scope of the novel concepts of the disclosure.

### DETAILED DESCRIPTION OF THE DRAWINGS

The accompanying drawings illustrate one or more embodiments of the invention and, together with the written description, serve to explain the principles of the invention. Wherever possible, the same reference numbers are used throughout the drawings to refer to the same or like elements of an embodiment, and wherein:

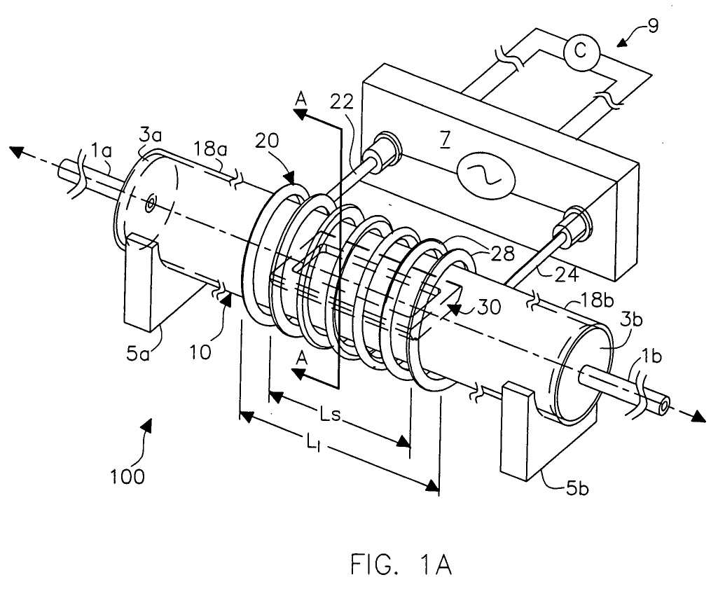

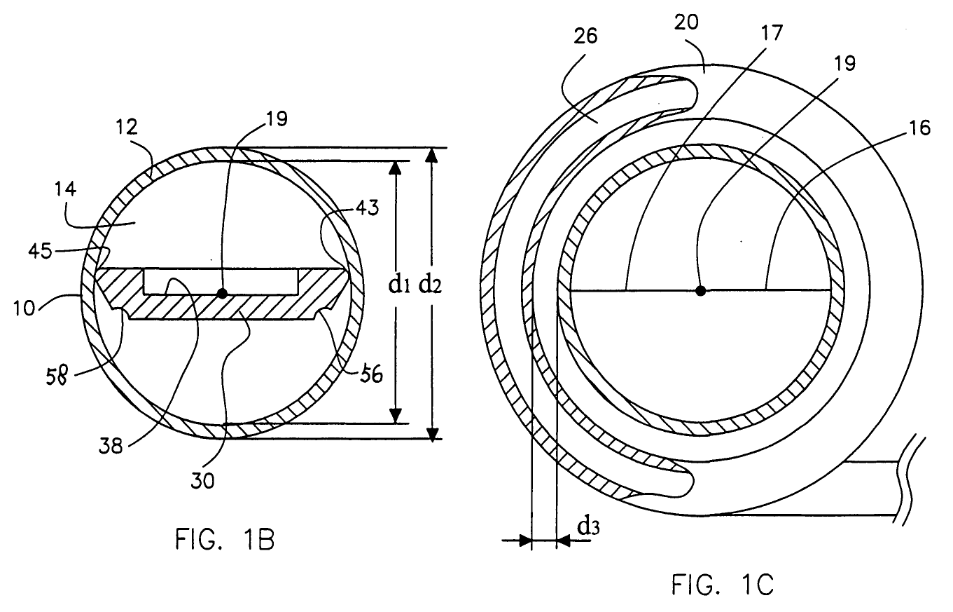

FIG. 1A is a perspective, partial view of an apparatus 100 according to one embodiment of the present invention.

FIG. 1B is a partial cross-sectional view of the apparatus 100 in FIG. 1A along line A-A but without conductive inductor 20.

FIG. 1C is a partial cross-sectional view of the apparatus 100 in FIG. 1A along line A-A but without conductive susceptor 30.

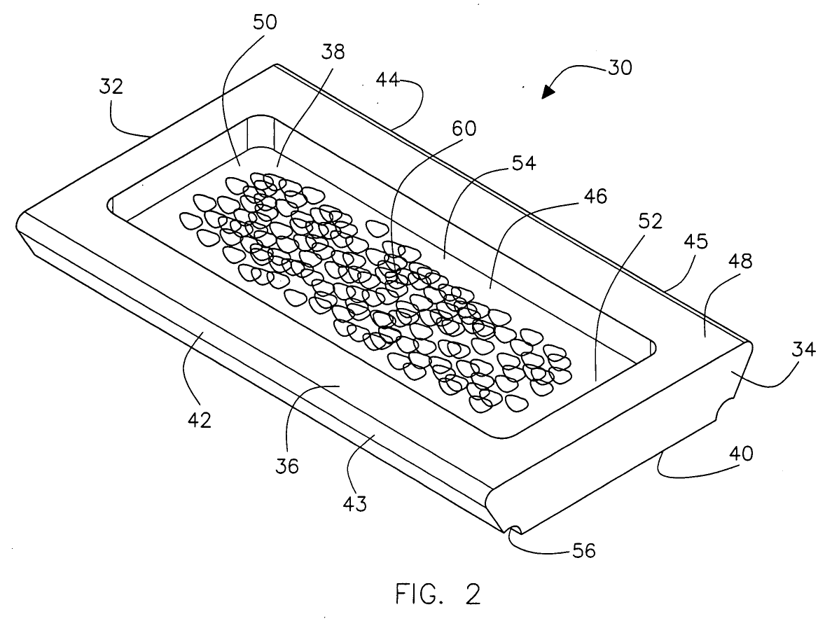

FIG. 2 is a perspective view of conductive susceptor 30 with catalysts 60 according to one embodiment of the present invention.

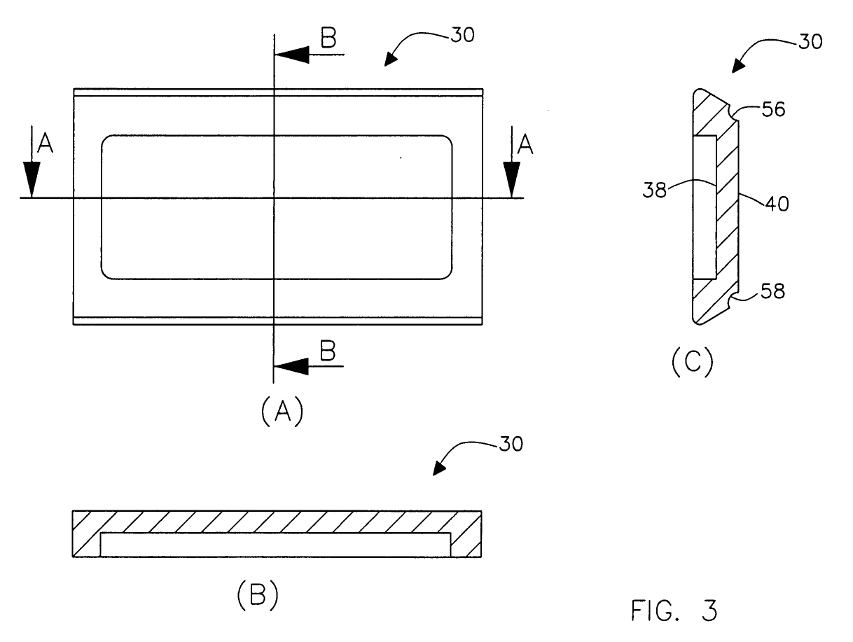

FIG. 3 (A) is a top plan view of the conductive susceptor 30 as shown in FIG. 2; (B) is a cross-sectional view of the conductive susceptor 30 as shown in FIG. 2 along line A-A in FIG. 3A; and (C) is a cross-sectional view of the conductive susceptor 30 as shown in FIG. 2 along line B-B in FIG. 3A, respectively.

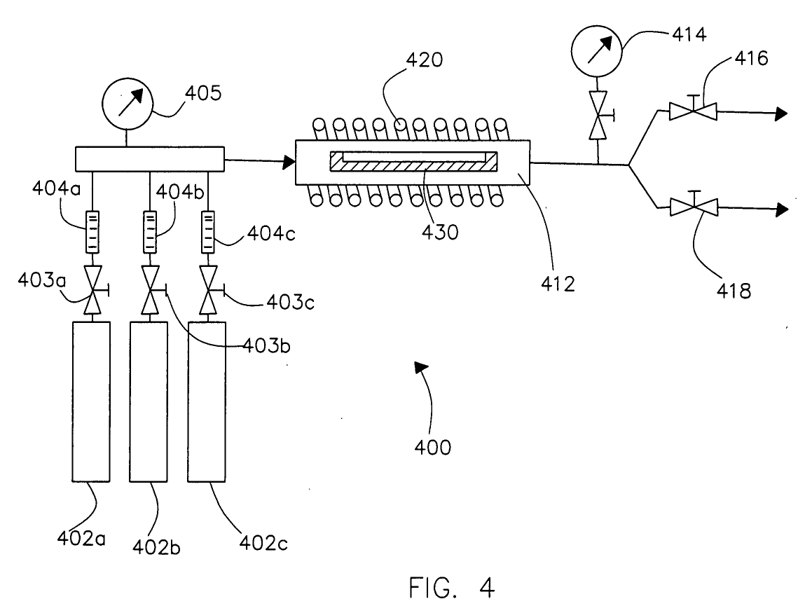

FIG. 4 illustrates an apparatus according to one embodiment of the present invention.

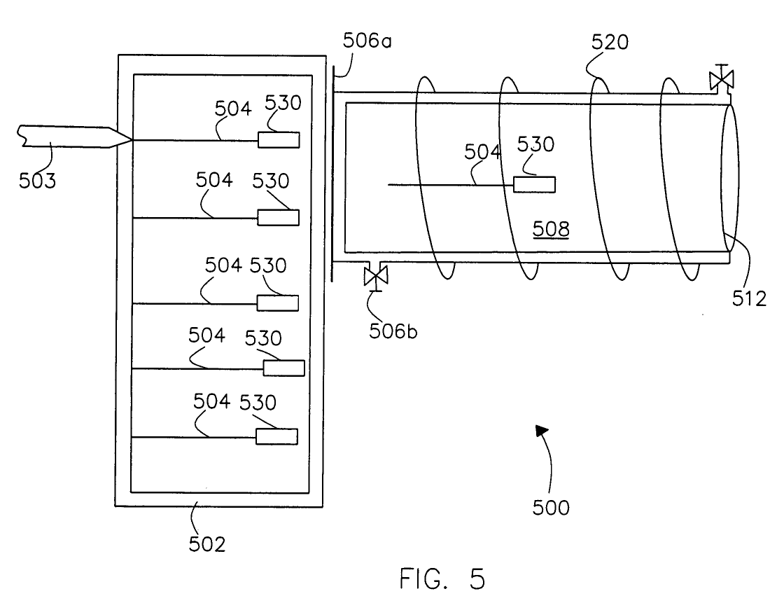

FIG. 5 illustrates an apparatus according to one embodiment of the present invention.

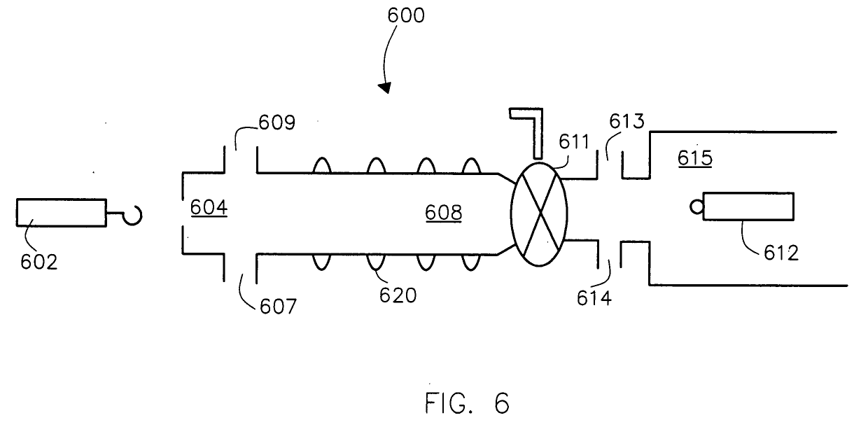

FIG. 6 illustrates an apparatus according to one embodiment of the present invention.

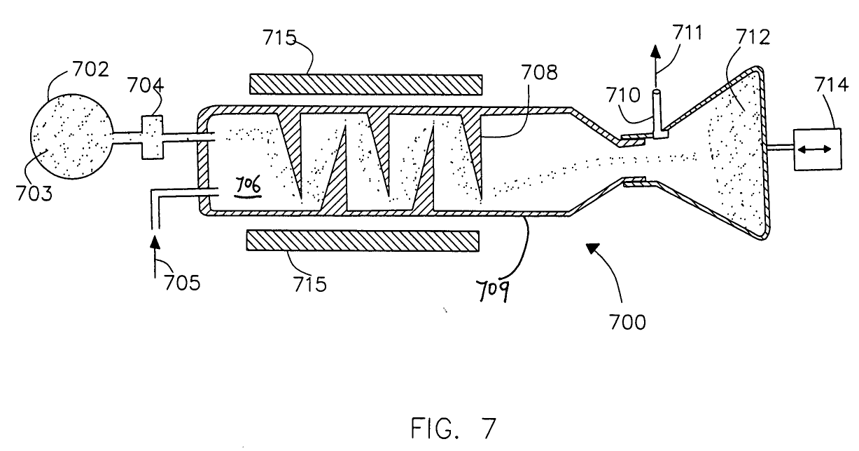

FIG. 7 illustrates an apparatus according to one embodiment of the present invention.

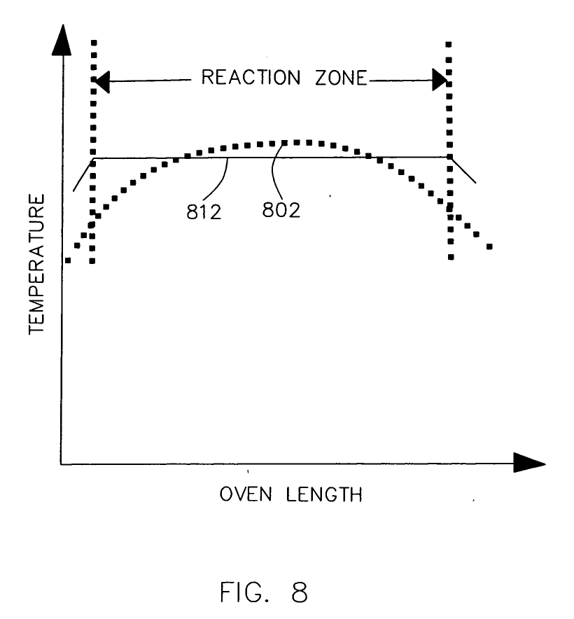

FIG. 8 illustrates temperature profiles of classical and inductively heated ovens for the generation of carbon nanostructures.

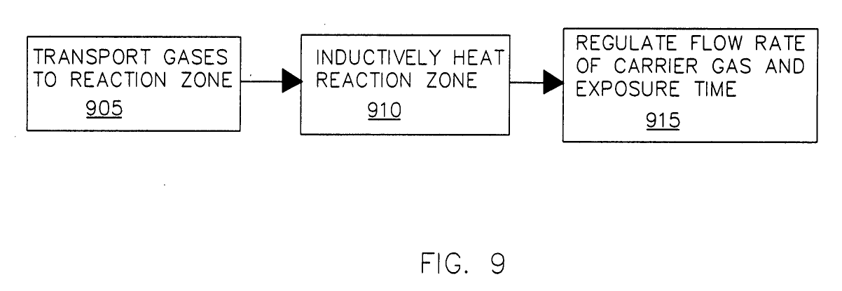

FIG. 9 is a flow diagram illustrating a method that relates to embodiments of the present invention.

FIG. 10 is a flow diagram illustrating a method that relates to embodiments of the present invention.

FIG. 11 is a flow diagram illustrating a method that relates to embodiments of the present invention.

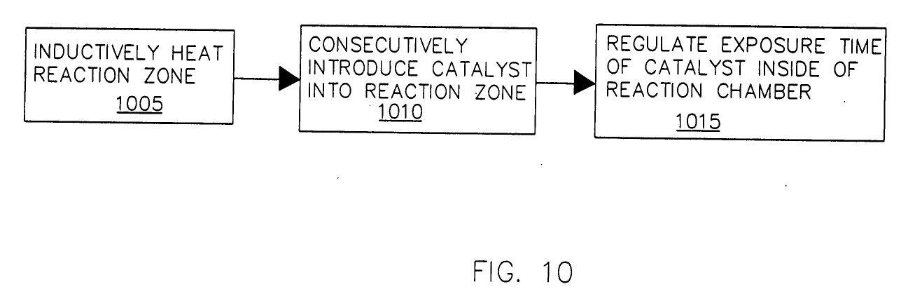

FIG. 12 (prior art) schematically shows a conventional heating mode.

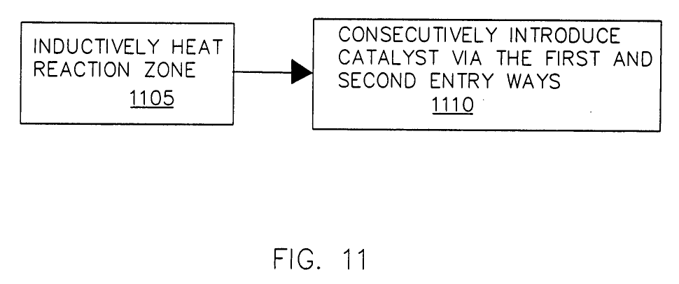

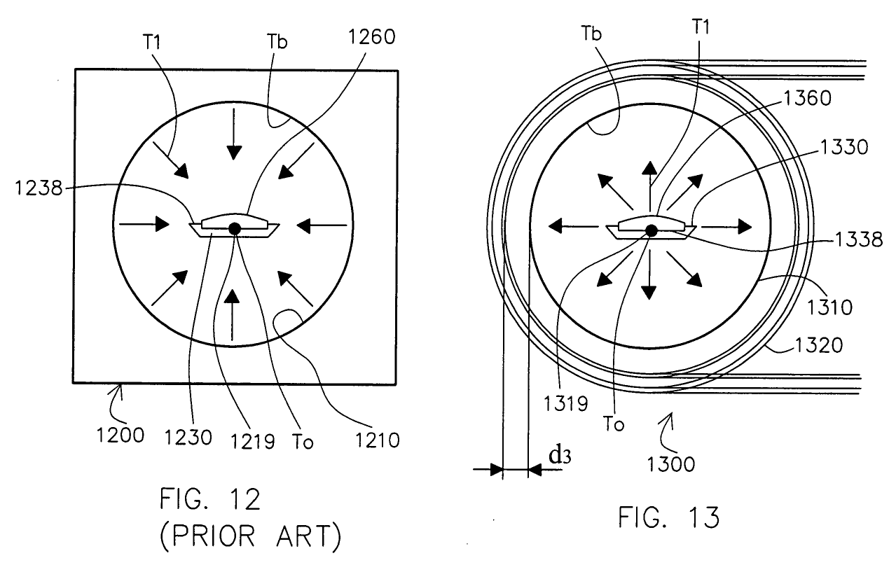

FIG. 13 schematically shows a heating mode that relates to embodiments of the present invention.

FIG. 14 is a TEM image of carbon nanostructures obtained under CVD heating mode from ethylene/hydrogen with catalysts Fe:Co on a Titanium rod with a layer of TiO₂ (susceptor).

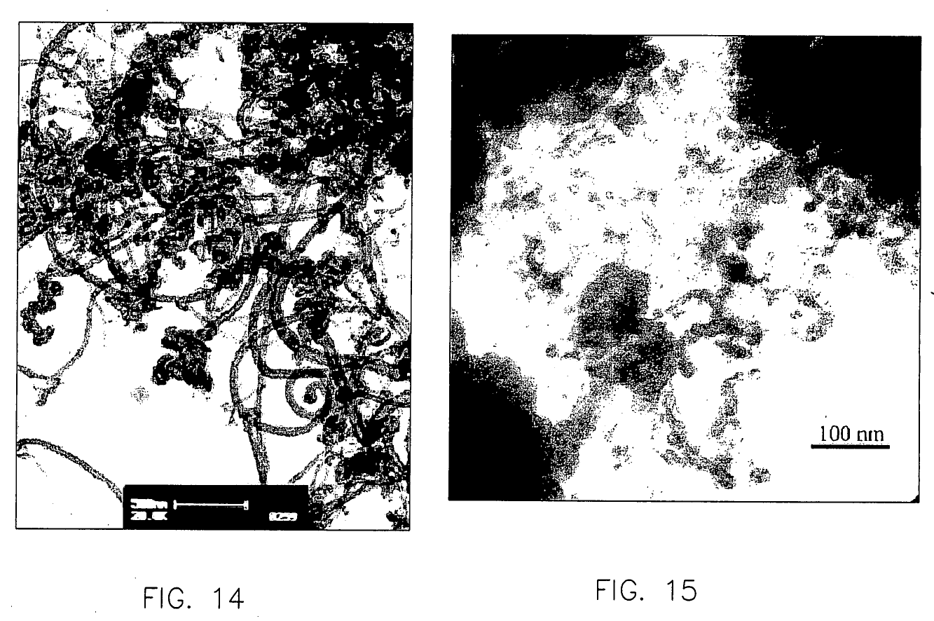

FIG. 15 is a TEM image of carbon nanostructures obtained under the same conditions under which the carbon nanostructures corresponding to the TEM image of FIG. 14 were obtained but using IH heating mode according to one embodiment of the present invention.

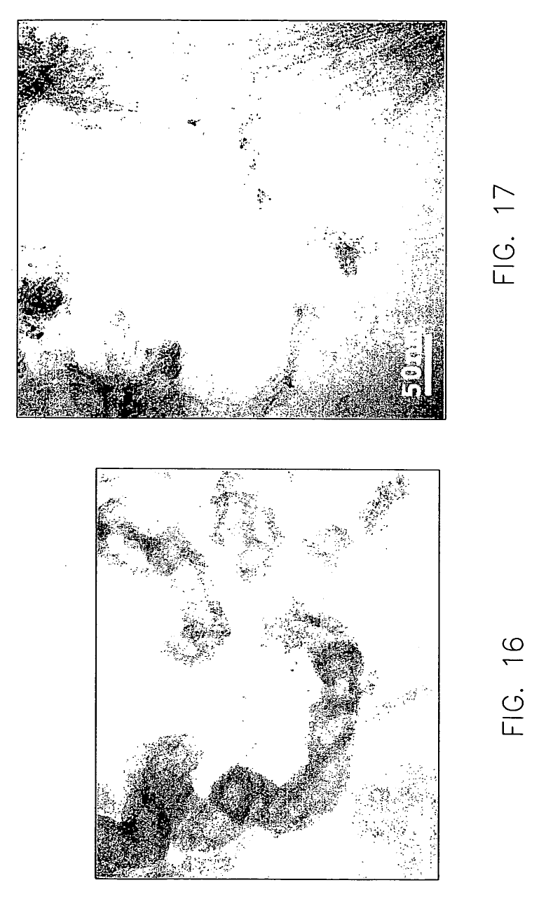

FIG. 16 is a TEM image of carbon nanostructures obtained under CVD heating mode from Methane(40 ml/min)/Argon (350 ml/min) with catalysts Fe:Mo:Al₂O₃ (1:0.2:16) on a Mo boat (susceptor).

FIG. 17 is a TEM image of carbon nanostructures obtained under the same conditions under which the carbon nanostructures corresponding to the TEM image of FIG. 16 were obtained but using IH heating mode according to one embodiment of the present invention.

### DETAILED DESCRIPTION

The present invention is more particularly described in the following examples that are intended as illustrative only since numerous modifications and variations therein will be apparent to those skilled in the art. Various embodiments of the invention are now described in detail. Referring to the drawings FIGS. 1-17, like numbers indicate like components throughout the views. As used in the description herein and throughout the claims that follow, the meaning of “a”, “an”, and “the” includes plural reference unless the context clearly dictates otherwise. Also, as used in the description herein and throughout the claims that follow, the meaning of “in” includes “in” and “on” unless the context clearly dictates otherwise. Moreover, titles or subtitles may be used in the specification for the convenience of a reader, which shall have no influence on the scope of the present invention. Additionally, some terms used in this specification are more specifically defined below.

### DEFINITIONS

The terms used in this specification generally have their ordinary meanings in the art, within the context of the invention, and in the specific context where each term is used.

Certain terms that are used to describe the invention are discussed below, or elsewhere in the specification, to provide additional guidance to the practitioner in describing the apparatus and methods of the invention and how to make and use them. For convenience, certain terms may be highlighted, for example using italics and/or quotation marks. The use of highlighting has no influence on the scope and meaning of a term; the scope and meaning of a term is the same, in the same context, whether or not it is highlighted. It will be appreciated that the same thing can be said in more than one way. Consequently, alternative language and synonyms may be used for any one or more of the terms discussed herein, nor is any special significance to be placed upon whether or not a term is elaborated or discussed herein. Synonyms for certain terms are provided. A recital of one or more synonyms does not exclude the use of other synonyms. The use of examples anywhere in this specification, including examples of any terms discussed herein, is illustrative only, and in no way limits the scope and meaning of the invention or of any exemplified term. Likewise, the invention is not limited to various embodiments given in this specification. Furthermore, subtitles may be used to help a reader of the specification to read through the specification, which the usage of subtitles, however, has no influence on the scope of the invention.

As used herein, “around”, “about” or “approximately” shall generally mean within 20 percent, preferably within 10 percent, and more preferably within 5 percent of a given value or range. Numerical quantities given herein are approximate, meaning that the term “around”, “about” or “approximately” can be inferred if not expressly stated.

As used herein, “Fullerenes” refer to closed-cage molecules (e.g., C60) composed entirely of sp2-hybridized carbons, arranged in hexagons and pentagons.

As used herein, “carbon nanostructures” refer to carbon fibers or carbon nanotubes that have a diameter of 1 μm or smaller which is finer than that of carbon fibers. However, there is no particularly definite boundary therebetween carbon fibers and carbon nanotubes. By a narrow definition, the material whose carbon faces with hexagon meshes are almost parallel to the axis of the corresponding carbon tube is called a carbon nanotube, and even a variant of the carbon nanotube, around which amorphous carbon exists, is included in the carbon nanotube.

As used herein, “single wall nanotube” or “SWNT” refers to a carbon nanotube having a structure with a single hexagon mesh tube (graphene sheet).

As used herein, “multi-wall nanotube” or “MWNT” refers to a carbon nanotube made of multilayer graphene sheets.

As used herein, “carbon nanotubes” refers to several of SWNTs, MWNTs, or a combination of them.

As used herein, “resistance heating method” refers to a method in the art to synthesize carbon nanotubes, in which one is to heat and vaporize graphite by bringing the tips of two graphite in contact with each other in rare gas, and applying several tens to several hundreds of amperes of a current.

As used herein, “arc discharge method” refers to a method in the art to synthesize fullerenes and carbon nanotubes by generating arc discharge in rare gas such as He and Ar while using graphite rods as an anode and a cathode associated with a chamber. In operation, the tip of the anode reaches a high temperature of 4,000° C. or more by arc plasma generated by the arc discharge, then the tip of the anode is vaporized, and a large quantity of carbon radicals and neutral particles are generated. The carbon radicals and neutral particles collide repeatedly in the plasma to generate carbon radicals and ions, and become soot containing fullerenes and carbon nanotubes to be deposited around the anode and cathode and on the inner wall of the chamber.

As used herein, “laser ablation method” refers to a method in the art to synthesize fullerenes and carbon nanotubes by irradiating pulse YAG laser beam on a graphite target, generating high density plasma on the surface of the graphite target, and generating fullerenes and carbon nanotubes. One characteristic of the method is that carbon nanotubes with relatively high purity can be obtained even at a growth temperature of more than 1,000° C.

As used herein, “chemical vapor deposition method” or “CCVD” refers to a method in the art to synthesize fullerenes and carbon nanotubes by using acetylene gas, methane gas, or the like that contains carbon as a raw material, and generating carbon nanotubes in chemical decomposition reaction of the raw material gas. Among other things, the chemical vapor deposition depends on chemical reaction occurring in the thermal decomposition process of the methane gas and the like serving as the raw material, thereby enabling the manufacture of carbon nanotubes having high purity.

As used herein, “reaction zone” refers to a three-dimensional area inside a nanostructure reactor where hydrocarbon molecules are heated to produce carbon molecules.

### OVERVIEW OF THE INVENTION

In one aspect, the present invention relates to an apparatus and methods for making nanostructures. Referring now first to FIGS. 1-3, a nanostructures growth apparatus 100 according to an embodiment of the present invention is shown. The apparatus 100 has a cylindrical process chamber 10, which has a body portion 12 defining a bore 14 therein and a geometric central plane 16 passing through a geometric center 19. As shown in FIG. 1B, the cross-section view of the cylindrical process chamber 10 has a first circle with a diameter d₁ corresponding to the inner surface of the body portion 12, and a second circle with a diameter d₂ corresponding to the outer surface of the body portion 12, respectively. These two circles are concentric, and the center for each of the two circles overlaps with the geometric center 19. Diameter d₁ and diameter d₂ can be chosen to fit different design needs as known to people skilled in the art as long as d₁<d₂. In one example, diameter d₁ is 25 mm and diameter d₂ is 28 mm. The body portion 12 is defined between a first end 18a, and an opposite, second end 18b.

The cylindrical process chamber 10 further has a first seal 3a for sealing the first end 18a, and an opposite, second seal 3b for sealing the second end 18b, respectively.

An inlet tube 1a can be used for interconnecting through the first seal 3a to establish a fluid communication with the bore 14 of the cylindrical process chamber 10, and an outlet tube 1b can be used for interconnecting through the second seal 3b to establish a fluid communication with the bore 14 of the cylindrical process chamber 10, respectively. Inlet tube la and outlet 1b are used to transport carbon feedstock and/or carrier gas in to and out from the bore 14 of the cylindrical process chamber 10, among other things. Inlet tube la and outlet 1b may also be connected to other control device(s) (not shown). Additional inlet(s) and/or outlet(s) may also be utilized.

At least one holder may be used for holding the cylindrical process chamber 10. As shown in FIG. 1, holder 5a is used for holding the cylindrical process chamber 10 at the first end 18a, and holder 5b is used for holding the cylindrical process chamber 10 at the second end 18b, respectively. Other types of holding means such as one or more hangers may also be used.

The process chamber 10 can take other geometric shapes. For example, the process chamber 10 can be spherical. The cylindrical process chamber 10 can be made of a substantially non-conductive material such glass. In one embodiment, the cylindrical process chamber 10 is substantially made of quartz. The cylindrical process chamber 10 may be made of other types of materials including conductive material.

The apparatus 100 also has a conductive inductor 20, as shown in FIGS. 1A and 1C, in the form of coils 28 that are substantially uniformly surrounding the outer surface of the body portion 12 of the cylindrical process chamber 10 defining a reaction zone in the bore 14 with a longitudinal length L_{I}. Coils 28 are positioned in relation to the body portion 12 of the cylindrical process chamber 10 such that there is a distance d₃ between the coils 28 and the outer surface of the body portion 12 of the cylindrical process chamber 10, as shown in FIG. 1C. Distance d₃ can be any value in the range of 0 to 10 cm.

The conductive inductor 20 can be made from at least one of metals, alloys, and conducting polymeric materials. In one embodiment, the conductive inductor 20 is substantially made from copper. The conductive inductor 20 is formed with a copper tube defining a channel 26 therein for circulating a coolant related to a coolant source 9. The coolant can be a gas, a liquid, or a combination of them. For examples, water can be used as coolant. The conductive inductor 20 is electrically coupled to an AC power supply 7 through a first end 22, and a second end 24, respectively. For example, a high or RF (radio frequency) frequency generator with typical parameters 1.3 MHz and 5 kW can be used as an AC power supply 7.

The apparatus 100 further has a conductive susceptor 30, as shown in FIG. 3, that has a first end portion 32, an opposite, second end portion 34, and a body portion 36 defined therebetween with a longitudinal length Lₛ. The body portion 36 defines a recess 46 with a supporting surface 38 for supporting catalysts 60. The supporting surface 38 can be flat, sloped, or curved. The body portion 36 of the conductive susceptor 30 is formed with a bottom surface 40, a first side surface 42, and a second, opposite side surface 44. Alternatively, the body portion can be formed such that the supporting surface 38 is the tope surface of the body portion.

The conductive susceptor 30 can be made of a substantially conductive material. In one embodiment, the conductive susceptor 30 is made of a substantially conductive material that is chemically compatible to carbon and its compounds, which means this material does not significantly affect or interfere with chemical properties of the carbon-based nanostructures. The substantially conductive material that is chemically compatible to carbon and its compounds is graphite, which has been used as a preferred material for the conductive susceptor. Alternatively, the substantially conductive material comprises at least one of metals, alloys, and ferromagnetic materials. For examples, titanium, stainless steel, iron, molybdenum, and any of their combinations can be used to practice the present invention.

The body portion 36 of the conductive susceptor 30 is formed with a bottom surface 40, a first side surface 42, and a second, opposite side surface 44. In one embodiment, the first side surface 42 has a sloped surface, and the second, opposite side surface 44 has a sloped surface such that when the conductive susceptor 30 is positioned in the reaction zone in the bore 14 of the cylindrical process chamber 10, there is a space formed between the first side surface 42 and the inner surface of the body portion 12 of the cylindrical process chamber 10, and there is a space formed between the second side surface 44 and the inner surface of the body portion 12 of the cylindrical process chamber 10, respectively, for facilitating fluid communication inside the bore 14, as shown in FIG. 1B.

The first side surface 42 further has an edge portion 43 formed with a curvature, and the second, opposite side surface 44 further has an edge portion 45 formed with a curvature such that when the conductive susceptor 30 is positioned in the reaction zone in the bore 14 of the cylindrical process chamber 10, as shown in FIG. 1B, the edge portion 43 of the first side surface 42 and the edge portion 45 of the second side surface 44 are complimentarily in contact with and supported by corresponding parts of the inner surface of the body portion 12 of the cylindrical process chamber 10, respectively. Alternatively, a conductive susceptor can be positioned in the bore of a process chamber through other supporting means with or without in direct contact with the inner surface of the process chamber. For example, as shown in FIG. 5 and discussed in more details infra, a supporting extension member 504 is used to position a corresponding conductive susceptor 530 in and out of a reaction zone 508.

Still referring to FIG. 1B, the body portion 36 of the conductive susceptor 30 is formed such that when the conductive susceptor 30 is positioned in the reaction zone in the bore 14 of the cylindrical process chamber 10, there is a space formed between the bottom surface 40 and the inner surface of the body portion 12 of the cylindrical process chamber 10 for facilitating fluid communication inside the bore 14. Moreover, there is a space formed between the supporting surface 38 and the inner surface of the body portion 12 for facilitating fluid communication inside the bore 14 and allowing nanostructures to grow.

The body portion 36 of the conductive susceptor 30 is formed with a first groove 56 interconnecting the bottom surface 40 and the first side surface 42, and a second groove 58 interconnecting the bottom surface 40 and the second side surface 44, respectively, for facilitating fluid communication inside the bore 14.

The recess 46 is defined by edge portion 48 of the body portion 36 of the conductive susceptor 30 and the supporting surface 38 and configured such that there are no sharp corners connecting a first end portion 50, an opposite, second end portion 52, and a middle portion 54 that define the recess 46 with the supporting surface 38. In other words, the recess 46 is formed such that a first degree derivative can be obtained along the boundaries of the recess 46.

The longitudinal length L_{I} of the reaction zone and the longitudinal length Lₛ of the conductive susceptor 30 satisfy the following relationship:
Lₛ<L_{I},
which allows the conductive susceptor 30 to be uniformly heated during an operation. However, the present invention can be practiced with the relationship Lₛ=or>L_{I}.

In one embodiment, Lₛ is about 100 mm, the depth of the recess 46 is about 5 mm, the width of the recess 46 is about 20 mm, d₁ is about 25 mm, the width of the bottom surface 40 is about 15 mm, and the thickness of the conductive susceptor 30 is about 10 mm. Other dimensions can also be chosen to practice the present invention.

In operation, the conductive susceptor 30 is positioned in the reaction zone in the bore 14 of the cylindrical process chamber 10 such that the supporting surface 38 is substantially overlapping with the geometric central plane 16. The supporting surface 38 effectively divides the bore 14 into an upper space and a lower space. The conductive inductor 20 allows an alternating current to pass through to generate an electromagnetic field with a frequency at least in the reaction zone and induce current in the conductive susceptor 30 so as to generate a heat flow from the conductive susceptor 30 to the body portion 12 of the cylindrical process chamber 10 to allow nanostructures to be grown in the bore 14 of the cylindrical process chamber 10. Note that because the catalysts 60 are metallic, additional current may be induced therein as well, further contributing to the efficient and uniform heating mode, i.e. inductive heating (“IH”) mode, allowed by the present invention.

The induced current penetrates into the conductive susceptor 30 a distance δ satisfying the following relationship:
δ=(2/ωμσ)^{1/2}
wherein ω is the angular frequency of the electromagnetic field, σ is the conductivity of the conductive susceptor 30, and μ is the absolute magnetic permeability of the conductive susceptor 30, and the induced current in the conductive susceptor 30 generates the heat flow by absorbing the energy, P, from the electromagnetic field satisfying the following relationship:
P=Hₒ² 2π(ωμ/σ)^{1/2}
with Hₒ being an amplitude of the electromagnetic field, which is known as the “skin effect” in physics.

Referring now to FIG. 13, a nanostructures growth apparatus 1300 according to another embodiment of the present invention is schematically shown. The apparatus 1300 has a process chamber 1310 that has a body portion defining a bore therein, a conductive inductor 1320, and a conductive susceptor 1330 with a supporting surface 1338 for supporting catalysts 1360 and positioned in the bore of the process chamber 1310 so that the supporting surface 1338 is overlapping with a plane having the center 1319, wherein the conductive inductor 1320 is configured and positioned in relation to the cylindrical process chamber 1310 such that, in operation, the conductive inductor 20 allows an alternating current to pass through to generate an electromagnetic field with a frequency at least in a reaction zone in the bore and induce current in the conductive susceptor 1330 so as to generate a heat flow T1 from the conductive susceptor 1330, where the temperature is denoted as To, to the body portion of the process chamber 1310, where the temperature is denoted as Tb, with the relationship Tb<To, to transfer heat.

In contrast, in traditional set up for making nanostructures, as schematically shown in FIG. 12, an apparatus 1200 has an oven 1210 that has a body portion defining a bore therein, and a susceptor 1230 with a supporting surface 1238 for supporting catalysts 1260 and positioned in the bore of the oven 1210, wherein the oven 1210 is heated from outside such that, in operation, a heat flow T1 from the inner surface 1210 of the oven 1200, where the temperature is denoted as Th, to the center 1219 of the oven 1210, where the temperature is denoted as To, with the relationship Tb>To, to transfer heat. In other words, the direction of heat transfer in the configuration as shown in FIG. 13 and according to an embodiment of the present invention is away from the center of the process chamber, while the direction of heat transfer in a traditional configuration as shown in FIG. 12 is in a reversed direction, i.e., to the center of the oven.

The temperature distributions along the main axes of classical oven and inductive heating chamber are shown in FIG. 8. These distributions indicate the thermal stability in the reaction zone. In particular, the uniform temperature line 812 provided by practicing the present invention across the reaction zone of the inductive heating process versus the non-uniform gradient curve 802 of a classical heating process is shown. The lack of uniformity in a classical heating process is directly responsible for a lack of purity in reaction products. In contrast, the present invention allows a substantially uniform temperature distribution longitudinally across the reaction zone.

Nanostructure reactors that implement CCVD methods require that hydrocarbon molecules be deposited on a heated catalyst material. Metal catalysts are typically used to disassociate the hydrocarbon molecules. Using hydrocarbons as a carbon source, the hydrocarbons flow into a reaction zone of a nanostructure reactor, where the hydrocarbons are heated at a high temperature. The dissociation of the hydrocarbon breaks the hydrogen bond, thus producing pure carbon molecules. Further, at high temperatures the carbon forms carbon nanotubes.

A significant aspect of practicing the present invention with CCVD technology is that in the instance Radio-Frequency (RF) energy is used to induce heating for a CCVD reaction, the heating does not necessarily require the generation of plasma. For this reason, the formation of nanomaterials can occur inside a reaction zone of a CCVD reactor that is filled with an induction field.

A CCVD reactor with inductive heating enables the control of most of the physical and chemical parameters that influence the nucleation and the growth of highly pure carbon nanostructures. Some of the most important parameters that influence the nucleation and growth of carbon nanostructures are the nature and support of the catalyst, the hydrocarbon source and concentration, flow rate and type of carrier gas, time of reaction, temperature of reaction and the thermal stability in the reaction zone.

Thus, according to the present invention, inductive heating directly heats a material, therefore making methods that utilize inductive heating exceptionally efficient. Further, because of skin effect, heating is localized wherein the heated area is simply and efficiently controlled by the size and shape of an inductor coil. Another advantage of inductive heating is that the time required for the catalyst particles to reach the temperature of reaction is much shorter in comparison to classical heating methods. The time required to produce a batch of nanostructures by inductive heating is approximately one third of the time compared to a classical oven. In a further comparison, inductive heating reaches reaction temperatures almost instantaneously as compared with classical heating methods.

Inductive heating can be used for a plurality of metallic catalysts on metal oxide supports and carrier/hydrocarbon or carrier/heteroatom source gas combinations. The specific types of nanostructures that are produced are a function of a chosen catalysts and a carrier gas (e.g., argon, nitrogen, hydrogen, helium, or mixtures of these gases in various ratios). For carbon nanostructures, hydrocarbon feedstock can be gaseous (e.g., methane, ethylene, acetylene, or the like), liquid (e.g., xylene, benzene, n-hexane, alcohol, or the like), or solid (e.g., anthracene, naphthalene, or the like). The above-mentioned reasons make inductive heating suitable for large-scale carbon nanostructure production. Additionally, embodiments of the present invention can also be practiced with modifications for the assembly of non-carbon based nanomaterials.

### EXAMPLES AND IMPLEMENTATIONS

Without intent to limit the scope of the invention, further exemplary methods and their related results according to the embodiments of the present invention are given below. Note again that titles or subtitles may be used in the examples for convenience of a reader, which in no way should limit the scope of the invention. Moreover, certain theories are proposed and disclosed herein; however, in no way they, whether they are right or wrong, should limit the scope of the invention.

Additional Experiments:

For additional experiments results shown in Table 1 below, catalysts were placed in all cases on a susceptor, which may be inductively heated. A titanium rod (5 mm diameter, 120 mm length) used as susceptor was electrochemically oxidized in 3% H₃PO₄ solution at 20 V constant voltage to obtain an adherent porous surface layer of TiO₂. Other materials such as Fe, Mo or graphite have been also utilized to practice the present invention.

The catalysts were prepared by evaporating nitrate solutions directly on the susceptor or by electrochemical deposition in the case of Co and Pd. The resulting catalyst deposit was heated in air at 400° C. for 1 hour.

For CCVD synthesis, the susceptor axially centered by fixing the end (without catalyst) in a small ceramic tube, was introduced in a quartz tube of 26 mm inner diameter, 1000 mm length, which was heated by an outer electric furnace of 500 mm length. The catalysts were first activated “in situ” at 350° C. in a hydrogen flow before the hydrocarbon admission, which took place under the conditions described in the next section.

For IH (“inductive heating”), the outer furnace was replaced by a nine-coils inductor, of 30 mm inner diameter and 80 mm length and connected to a high frequency generator (1.3 MHz and 5 kW). The susceptor, covered with catalyst on a length of 60 mm, was completely surrounded by the inductor to allow a homogeneous heating.

The morphology of the carbon nanostructures was examined by transmission electron microscopy (“TEM”) using a Zeiss EM912 microscope, operated at 120 kV.

Results and Discussion

The results obtained under various conditions are listed in Table 1. The samples identified with sample codes CVD (“conventional outer furnace heating”), I1 and I2 were synthesized and processed exactly in the same conditions (20 hour in HCl 37%) except for the heating mode for comparison.

The characteristics of the products reveal at least two significant differences, as can be seen from FIGS. 14 and 15. The products of CVD show catalyst particles, which still remained encapsulated at the tip of the fibers. They were not found in sample I1. The open circles at the end of the nanofibers in I1 might be interpreted as open ends due to the breaking of the nanofibers (they were all collected by scraping from the Ti rod) or to acid dissolution of metal particles, which were not completely covered by carbon. The other samples were examined as-prepared in order to observe the catalyst particles. The hollow core fibers (often referred to as nanotubes) observed in sample I1 are significantly thinner, suggesting a higher growth rate with IH as thin fibers grow faster than the thick ones.

As set forth above and shown in FIGS. 12 and 13, it should be noted that there are differences between the two heating modes. With an outer furnace, the heating of catalyst particles is achieved by heat transfer (radiation and convection) from the reaction tube walls, while with IH the thermal gradient is in the opposite direction, from the susceptor to the catalyst, which are in direct contact. The inductive heating occurs due to the confinement of the induced currents and magnetic flux to a thin surface layer of an electric conductor subjected to a high-frequency field—the skin effect. The skin depth depends on the relative permeability and conductivity of the material. The conduction electrons of the metallic catalyst particles, might be directly affected by the high-frequency field. These effects, which do no occur during the conventional heating, may have consequences on the growth and morphology of the carbon nanostructures.

CCVD experiments (ethylene 80; hydrogen 20 vol %, static) on Pd/La₂O₃ resulted in herringbone-type carbon nanofibers, but with Pd/TiO₂ no deposit could be obtained at 600° C. However, at higher temperatures and in flow conditions, uniform diameter fibers were obtained for sample I5.

Experiments with more diluted ethylene in hydrogen flow were also performed because CCVD in hydrocarbon flow ensures a constant concentration of carbon species at the catalyst surface. For sample I8 only massive fibers (without hollow core) were obtained. The growth of full fibers at lower temperatures was reported to be determined by a slower nucleation rate. Under the gas flow conditions of I8 experiment, the slower nucleation rate of full fibers might be tentatively explained by an increased heat loss by convection.

The same ethylene/hydrogen flow conditions with another catalyst, Ni/Al₂O₃ on a molybdenum foil cylinder as susceptor, resulted in the sample I9. The XRD measurements for sample I9 (removed catalyst) resulted in the a d₀₀₂=0.348 nm interlayer spacing as compared to 0.3354 nm obtained for graphite single crystals. This value is in the range for nanotubes of about 100 nm diameter taking into account the relationship between d₀₀₂ and the diameter reported in the literature.

It is worth noting that IH can be also used for the floating catalyst-CCVD method. By using an 18 cm long graphite rod in a vertical arrangement, I6, carbon fibers without catalyst at the tip resulted.

The comparison of samples I3 and I1 shows that for the CCVD method under the same synthesis conditions, the IH compared to the outer furnace technique results in thinner fibers, consistent with a faster growth rate. The absence of the catalyst particles from the tip of the nanofibers obtained with IH in most of the results reported in Table 1, might suggest the growth by extrusion mechanism. Because this should be related to strong metal-support interaction, the role of IH is not entirely clear yet. Inducted currents might be present in the catalyst particles, enhancing the fluidity of active metal-carbon particles as an important characteristic related to the growth mechanism.

The experiments showed that the same yield could be obtained with IH as with conventional heating, but at 2-3 times lower energy consumption, if a suitable susceptor was selected.

FIGS. 16 and 17 are TEM images of carbon nanostructures obtained under the same conditions except heating mode, namely, from Methane(40 ml/min)/Argon (350 ml/min) with catalysts Fe:Mo:Al₂O₃ (1:0.2:16) on a Mo boat (susceptor). The carbon nanostructures in FIG. 16 were obtained from CVD heating, while the carbon nanostructures in FIG. 17 were obtained from IH heating according to one embodiment of the present invention.

TABLE 1
Characteristics of the carbon nanostructures obtained by
CCVD with outer furnace or IH under various conditions.

| | | | Main product | | |
|---|---|---|---|---|---|
| | | Synthesis | morphologies | Yield [mg/mg] | |
| Sample code | Heating | conditions | (o.d; i.d.) | (catalyst) | |
| (treatment) | mode | 1 h | [nm] | [mg/cm²] | |
| CVD (HCl, | Outer | Ethylene/H₂ 80 vol. | Hollow core fibers: | 14.8 | (15) |
| 20 h) | furnace | % ethylene) static | (20-50; 5-20) | | |
| | | at 0.35 bar | catalyst particles | | |
| | | Fe:CO(1:1)/Ti rod | encapsulated at tip | | |
| | | 600° C. | | | |
| I1 (HCl, | IH | Ethylene/H₂ (4:1) | Hollow core fibers | 5 | (5) |
| 20 h) | | static at 0.35 bar | (8-15; 3-5) | | |
| | | Fe:Co(1:1)/Ti rod | without catalyst | | |
| | | 600° C. | at tip | | |
| I2 (HCl, | IH | Ethylene/H₂ (4:1) | Closed tip fibers: | 6 | (5) |
| 20 h) | | static at 0.35 bar | (35-45; 25-35), | | |
| | | Fe:Co(1:1)/Fe rod | without catalyst | | |
| | | 600° C. | at tip | | |
| I3 | IH | Ethylene/H₂ (4:1) | Entangled fibers | 6.4 | (5.9) |
| | | static at 0.35 bar | with thin hollow | | |
| | | Co/Ti rod 600° C. | core: (15-20; | | |
| | | | 3-5) | | |
| (as prepared) | | | A few symmetric | | |
| | | | two-branches fibers | | |
| | | | on biconical metal | | |
| | | | particles (100; 10) | | |
| I4 | IH | Same condition as | Crenulated fibers, | 1.5 | (5) |
| | | I3, 1000° C. | no hollow core | | |
| (as-prepared) | | | Short multibranches | | |
| | | | fibers | | |
| I5 (as- | IH | Ethylene/H₂ (4:1); | Helical, uniform | 11 | (12) |
| prepared) | | 20 ml/min. Pd/Ti | diameter fibers, | | |
| | | rod, 1000° C. | very thin hollow | | |
| | | | core, without | | |
| | | | catalyst particles | | |
| | | | ˜75 nm o.d. | | |
| I6 (vertical | IH | 1.8% ferrocene, 0.4 | Meandering tube-like | (1 g/h) | |
| floating) | | tiophene in n-hexane, | fibers, 30-40 nm | | |
| | | 0.04 nl/min H₂flow | o.d., no catalyst | | |
| | | 80 ml/min | at tip | | |
| (as-prepared) | | | “Stacked-cone” type | | |
| | | | fibers | | |
| I8 (as- | IH | Ethylene 16 vol. % | Less organized | 8.2 | (6.8) |
| prepared) | | in H₂ 100 ml/min. | fibers, 20-50 nm | | |
| | | Co/Ti rod, 600° C. | o.d. catalyst | | |
| | | | encapsulated | | |
| I9 | IH | Ethylene 16 vol. % | Fibers with very | 2.2 | (6.2) |
| | | in H₂ 100 ml/min. | thin hollow core, | | |
| | | on Ni-1A₂O₃/Mo | (40-60; 5-10), | | |
| | | foil, 600° C. | aspect ratio ˜200 | | |
| (as-prepared) | | | Thin entangled | | |
| | | | fibers (10-20; 4-8) | | |
| | | | all without catalyst | | |
| | | | at tip | | |

The amount of product in mg/cm² refers to the area of substrate covered with catalyst.

Additional Aspects of the Present Invention

The present invention is further described in reference to FIG. 4. FIG. 4 illustrates an embodiment of the present invention that relates to the transport of an aerosolized catalyst 402a (in this instance hydrogen) and hydrocarbon 402b (or another elemental feedstock source) together into a heated reaction zone 408 of a nanostructure reactor 400 by a carrier gas 402c. The reaction zone area 408 in this instance is located within the confines of the quartz tube 412, wherein the quartz tube 412 and the reaction zone 408 are heated by inductor coils 420. A catalyst (not shown) is situated upon a susceptor 430. The thermal gradient from the susceptor 430 is transferred to the catalyst, therefore greatly increasing the efficiency of heat transfer to the catalyst. Note that a susceptor may comprise an appropriate material on which the catalyst may be deposited. Further, the surface of the susceptor should allow for 15 superior adherence between the catalyst and the susceptor in addition to providing an appropriate thermal contact for the catalyst.

The flow rate of the carrier gas 402c and the speed of the particles inside the reaction zone area 408 are regulated by input valves 403a, 403b, 403c and flow-meters 404a, 404b, 404c such that the time spent by a catalyst inside the reaction zone 408 is enough to allow the growth of the nanostructures having the dimensions, number of walls, and other features that are required by each application. Gas utilized within the reactor is transported out of the reactor 400 via a gas output valve 416 and a vacuum line 418. The input and output pressure of the gasses that are introduced into the reactor and vented out of the reactor are monitored by pressure gages 405 and 414, respectively.

FIG. 5 illustrates a further embodiment of the present invention comprising a nanostructure reactor 500, wherein the nanostructure reactor has a reaction zone 508. The nanostructure reactor 500 has a means that allows for the consecutive introduction of batches of a catalyst to the reaction zone 508, wherein the catalysts are positioned inside the reaction zone 508 for a time period that has been determined in order to facilitate the growth of desired nanostructures.

Within further aspects of the present embodiment the means for consecutively introducing batches of catalyst to the reaction zone comprises a carousel type chuck 502 (the chuck 502 being similar in shape and configuration to a Gattling gun magazine). The carousel type chuck 502 comprises several susceptor receptacles, each having a supporting extension member 504 and a corresponding susceptor 530 for supporting catalysts, that are secured and arranged in a circular configuration within the chuck 502. Further aspects of the present invention allow for the carousel shaped chuck 502 to be rotated by a dedicated mechanical device.

The supporting extension members 504 are used to consecutively insert batches of catalyst powder supported by a corresponding susceptor 530 into the reaction zone 508, for time periods that are long enough to produce desired nanostructures. The reaction zone 508 in this instance is located within the confines of the quartz tube 512. A trap door/valve 506a and hydrocarbon and inert gas inlet valve 506b situated at a first end of the quartz tube 512. The trap door/valve 506a functions to keep air out of the reaction zone 508 in addition to keeping hydrocarbon feedstock out of the carousel chuck 502. Therefore, when the trap door/valve 506a is open (on the occasion that a susceptor receptacle 504 is being moved into the reaction zone 508) then accordingly the valve 506b is closed. Further, a one-way gas exit valve that is situated at a second end of the quartz tube 512 to vent gases away from the reaction zone 508. The quartz tube 512 and thereby the reaction zone 508 are heated by the inductor coils 520 according to the present invention or even any other conventional thermal heating methods in further embodiments.

Once a respective receptacle, which has a supporting extension member 504 and a corresponding susceptor 530, inserting process is completed, another susceptor receptacle, which also has a supporting extension member 504 and a corresponding susceptor 530 containing the catalyst, is introduced into the reaction zone 508 by rotating the carousel chuck 502 into a predetermined position, thereafter the arm 503 is engaged to move the catalyst 530 into the reaction zone 508. This aspect of the present invention may be accomplished using a pneumatic, hydraulic or electrical device (not shown) to rotate the carousel chuck 502 and extend and retract the arm 503. This process enables increased production of nanostructures while still maintaining high quality and purity of the resultant products.

FIG. 6 illustrates another embodiment of the present invention that enables the consecutive introduction of catalyst in two opposing sides of a reactor 600 by way of susceptor transportation receptacles 602, 612 (the receptacles being flat in shape). Air locks 604, 615 are used to maintain a constant flow rate for the carrier and hydrocarbon or other feedstock gases inside the reactor area during the insertion or removal of receptacles. Carrier gases are input and output via a valve and flow meter (not shown) located at input 609 and output 607 ports of the reactor 600. Likewise, the carrier and feedstock gas combination is input and output via a valve and flow meter (not shown) located at input 613 and output 614 ports of the reactor 600.

An inlet ball valve 611 is used to seal the airlock 615; this aspect ensures that there is equilibrium of catalyst and all gases except for the feedstock gas. This enables the introduction of a new susceptor receptacle 602, 612 into the reactor 600 without upsetting the fluid dynamics inside of the reaction zone 608. As in other embodiments of the present invention the reaction zone 608 is heated by way of the inductor coils 620 or conventional thermal heating methods.

FIG. 7 illustrates a yet another embodiment of the present invention. The nanostructure reactor as illustrated in FIG. 7 provides for the consecutive introduction of batches of catalyst to the reaction zone 706. The reactor 700 has a catalyst tank 702, wherein the catalyst tank 702 is used to contain the catalyst powder 703. The catalyst tank 702 is further equipped with a catalyst feeder 704, wherein the catalyst feeder 704 vertically controls the introduction of catalyst powder 703 into the reaction zone 706.

Once the catalyst powder 703 is introduced into the reaction zone 706, the catalyst powder 703 is deposited upon and sifted between pluralities of baffles 708 that are situated within the reaction zone 706. The baffles 708 are configured in a staggered descending vertical arrangement, wherein each consecutive baffle 708 is attached to an opposite side of the quartz tube 709 than its predecessor was attached. As shown in FIG. 7, the baffles 708 further comprise a downward sloping shape, thus allowing for any material that is deposited upon a baffle 708 to be easily transferred to a lower level baffle 708.

Hydrocarbon or other feedstock and a carrier gas are input to the reactor via an input valve 705. The quartz tube 709 and the reaction zone 706 are heated by way of an inductor heater 715 or conventional thermal heating methods. The catalyst powder 703 is transferred between baffles 708 with the aid of a vibration inducing mechanism 714 that is in mechanical contact with the reactor 700. The vibration inducing mechanism vibrates the reactor 700, thus the vibrations along with gravity provides the force that is needed to sift the catalyst powder 703 from baffle 708 to baffle 708 through the reaction zone 706. Gases that are output from the process are vented through a filter 710, therefore the final product of carbon nanostructures is eventually sifted and collected in a container (not shown).

FIG. 9 shows a flow diagram that relates to an embodiment of the present invention that comprises a method for the production of nanostructures. At step 905 an aerosolized catalyst 402a and carbon feedstock 402b are transported to the reaction zone 408 of a nanostructure reactor 400 by a carrier gas 402c. At step 910 the inductive coils 110 inductively heat the reaction zone 408. Further, at step 915, at least the flow rate of the carrier gas 402c is regulated in addition to the time the catalyst is inside the reaction zone 408 in order to facilitate the growth of desired nanostructures.

A further aspect of the present embodiment provides a step for the regulation of the flow rates of the carrier gas 402c, aerosolized catalyst 402a and carbon feedstock 402b by flow-meters 404. In additional embodiments other predetermined elemental feedstocks may be substituted for the carbon feedstock.

FIG. 10 shows a flow diagram that relates to another embodiment of the present invention. At step 1005, the reaction zone 508, 706 of a nanostructure reactor 500, 700 is inductively heated. Next, at step 1010, batches of catalyst are consecutively introduced into the reaction zone 508, 706. Further, at step 1015, the time spent by the catalyst inside the reaction zone 508, 706 is regulated in order to facilitate the growth of desired nanostructures.

A further aspect of the present embodiment comprises a step of consecutively introducing batches of catalyst to the reaction zone 508 by using a carousel shaped chuck 502. Another aspect of the present invention provides a step for the catalyst that is being used within the present invention to be vertically introduced into the reaction zone 706. Thereafter, the catalyst is deposited upon and sifted between a plurality of baffles that are situated within the reaction zone 706. The catalyst being transferred between baffles with the aid of a vibration inducing mechanism that is contact with the reactor 700.

FIG. 11 shows a flow diagram that relates to yet another embodiment of the present invention. The embodiment comprises a method for the production of nanostructures wherein at step 1105, a reaction zone 608 of a nanostructure reactor 600 is inductively heated, the nanostructure reactor 600 comprising a first airlock 604 at a first end of the nanostructure reactor 600 and a second airlock 615 situated at a second end of the nanostructure reactor 600. At step 1110, catalysts are consecutively introduced to the reaction zone 608 via the first airlock 604 and the second airlock 615.

Aspects of the present embodiment provide steps for maintaining a constant flow rate for a carrier gas 402c and a carbon feedstock 402b inside the nanostructure reactor 600. Further aspects provide for the maintaining of a constant flow rate by the use of at least one air lock 604, 615.

Thus, the present invention further provides methods and apparatus for the high throughput generation of nanostructures using inductive heating, which increases productivity of generating nanostructures while maintaining the quality and purity of nanostructures. The present invention, in one aspect, relates to a technology for heating a reaction zone of a nanostructure reactor by the use of inductive heating. When used in a nanostructure reactor, inductive heating presents a uniform and stable temperature in the reaction zone of the reactor. Further, inductive heating is easily controlled and focused on catalyst particles.

Moreover, inductive heating consumes significantly lower energy as compared to classical heating technologies. When utilized within a nanostructure reactor inductive heating primarily heats the reactants within the reaction zone, thus at high temperatures, very little energy is transferred to the nanostructure reactor housing.

An embodiment of the present invention comprises a method for the production of nanostructures. The method comprises the steps of inductively heating a reaction zone of a nanostructure reactor and transporting an aerosolized catalyst and carbon feedstock to the reaction zone by a carrier gas. At least the flow rate of the carrier gas is regulated in addition to the time the catalyst is inside the reaction zone in order to facilitate the growth of desired nanostructures.

A further aspect of the present embodiment provides for the regulation of the flow rates of the carrier gas, aerosolized catalyst and carbon feedstock by flow-meters. In further embodiments other predetermined elemental feedstocks may be substituted for the carbon feedstock.

Another embodiment of the present invention comprises a method for the production of nanostructures wherein the method comprises the steps of inductively heating a reaction zone of a nanostructure reactor and consecutively introducing batches of catalyst into the reaction zone. Additionally, the time spent by the catalyst inside the reaction zone is regulated in order to facilitate the growth of desired nanostructures.

A further aspect of the present embodiment comprises a step of consecutively introducing batches of catalyst to the reaction zone by using a chuck, wherein the chuck comprises a carousel shape. Further, a plurality of receptacles are secured and arranged in a circular configuration within the chuck. Further aspects of the present invention provide for the carousel shaped chuck to be rotatable.

Another aspect of the present invention provides for a powder catalyst to be vertically introduced into the reaction zone. Thereafter, the catalyst is deposited upon and sifted between a plurality of baffles that are situated in a descending order within the reaction zone. The catalyst being transferred between baffles with the aid of a vibration inducing mechanism that is in contact with the reactor.

An additional embodiment of the present invention comprises a method for the production of nanostructures that comprises the steps of inductively heating a reaction zone of a nanostructure reactor, wherein the nanostructure reactor comprises a first airlock at a first end of the nanostructure reactor and a second airlock situated at a second end of the nanostructure reactor. Catalyst are consecutively introducing to the reaction zone via the first airlock and the second airlock.

Aspects of the present embodiment provide for the present invention to maintain a constant flow rate for a carrier gas and a carbon feedstock inside the nanostructure reactor. Further aspects provide for the maintaining of a constant flow rate by the use of at least one air lock.

A further embodiment of the present invention comprises an apparatus for the production of nanostructures comprising a nanostructure reactor, wherein the nanostructure reactor has a reaction zone. The nanostructure reactor further has a heating device, wherein the heating device heats the reaction zone. The nanostructure reactor also has a means for the consecutive introduction of batches of a catalyst to the reaction zone, wherein the catalysts are positioned inside the reaction zone for a time period that has been determined in order to facilitate the growth of desired nanostructures.

Within further aspects of the present embodiment the means for consecutively introducing batches of catalyst to the reaction zone comprises a carousel type chuck. Further, a plurality of receptacles, utilized for introducing the catalyst to the reaction zone, are secured and arranged in a circular configuration within the carousel type chuck. Additional aspects of the present invention allow for the carousel shaped chuck to be rotatable.

Yet further aspects of the present embodiment provide a means for consecutively introducing batches of catalyst to a reaction zone that comprises a catalyst tank for containing a catalyst powder. The catalyst tank has a catalyst feeder, wherein the catalyst feeder vertically controls the introduction of catalyst powder into the reaction zone. The catalyst is deposited upon and sifted between a plurality of baffles that are situated within the reaction zone. Further, the catalyst is transferred between the baffles situated within the reaction zone with the aid of a vibration inducing mechanism that is contact with the reactor.

In yet a further aspect of the present embodiment the nanostructure reactor comprises a first airlock at a first end of the nanostructure reactor and a second airlock at a second end of the nanostructure reactor. The nanostructure reactor has the capability to maintain a constant flow rate for a carrier gas and a carbon feedstock inside the nanostructure reactor. Additionally, the nanostructure reactor utilizes at least one air lock to maintain the constant flow of a respective gas.

Any of the above-mentioned embodiments alone or in combination will permit the continuous production of nanostructures. Further, any other methods that achieve the same result by controlling the above-mentioned pertinent factors are encompassed within the scope of this invention.

It will be apparent to those skilled in the art that various modifications and variations can be made in the present invention without departing from the scope or spirit of the invention. Other embodiments of the invention will be apparent to those skilled in the art from consideration of the specification and practice of the invention disclosed herein. It is intended that the specification and examples be considered as exemplary only, with a true scope and spirit of the invention being indicated by the following claim.

1. A nanostructures growth apparatus, comprising:
a. a cylindrical process chamber having a body portion defining a bore therein and a geometric central plane passing through a geometric center;
b. a conductive inductor in the form of coils surrounding the body portion of the cylindrical process chamber defining a reaction zone in the bore with a longitudinal length L_{I}; and
c. a conductive susceptor having a first end portion, an opposite, second end portion, and a body portion defined therebetween with a longitudinal length Lₛ, wherein the body portion defines a recess with a supporting surface for supporting catalysts,
wherein the conductive susceptor is positioned in the reaction zone in the bore of the cylindrical process chamber such that the supporting surface is substantially overlapping with the geometric central plane; and
wherein in operation, the conductive inductor allows an alternating current to pass through to generate an electromagnetic field with a frequency at least in the reaction zone and induce current in the conductive susceptor so as to generate a heat flow from the conductive susceptor to the body portion of the cylindrical process chamber to allow nanostructures to be grown in the bore of the cylindrical process chamber.

2. The apparatus of claim 1, wherein the cylindrical process chamber further has a first end, and an opposite, second end defining the body portion therebetween.

3. The apparatus of claim 2, wherein the cylindrical process chamber further has a first seal for sealing the first end, and an opposite, second seal for sealing the second end, respectively.

4. The apparatus of claim 3, further comprising an inlet tube interconnecting through the first seal in fluid communication with the bore of the cylindrical process chamber, and an outlet tube interconnecting through the second seal in fluid communication with the bore of the cylindrical process chamber, respectively.

5. The apparatus of claim 3, further comprising at least one holder for holding the cylindrical process chamber.

6. The apparatus of claim 1, wherein the cylindrical process chamber is made of a substantially non-conductive material.

7. The apparatus of claim 6, wherein the substantially non-conductive material comprises glass.

8. The apparatus of claim 1, wherein the cylindrical process chamber is substantially made of quartz.

9. The apparatus of claim 1, wherein the conductive inductor is made from at least one of metals, alloys, and conducting polymeric materials.

10. The apparatus of claim 9, wherein the conductive inductor is substantially made from copper.

11. The apparatus of claim 9, wherein the conductive inductor comprises a tube defining a channel therein for circulating a coolant.

12. The apparatus of claim 1, wherein the conductive inductor is electrically coupled to an AC power supply.

13. The apparatus of claim 1, wherein the conductive susceptor is made of a substantially conductive material.

14. The apparatus of claim 13, wherein the conductive susceptor is made of a substantially conductive material that is chemically compatible to carbon and its compounds.

15. The apparatus of claim 14, wherein the substantially conductive material that is chemically compatible to carbon and its compounds comprises graphite.

16. The apparatus of claim 13, wherein the substantially conductive material comprises at least one of metals, alloys, and ferromagnetic materials.

17. The apparatus of claim 1, wherein the body portion of the conductive susceptor is formed with a bottom surface, a first side surface, and a second, opposite side surface.

18. The apparatus of claim 17, wherein the first side surface comprises a sloped surface, and the second, opposite side surface comprises a sloped surface such that when the conductive susceptor is positioned in the reaction zone in the bore of the cylindrical process chamber, there are a space formed between the first side surface and the inner surface of the body portion of the cylindrical process chamber, and a space formed between the second side surface and the inner surface of the body portion of the cylindrical process chamber, respectively, for facilitating fluid communication inside the bore.

19. The apparatus of claim 18, wherein the body portion of the conductive susceptor is formed such that when the conductive susceptor is positioned in the reaction zone in the bore of the cylindrical process chamber, there is a space formed between the bottom surface and the inner surface of the body portion of the cylindrical process chamber for facilitating fluid communication inside the bore.

20. The apparatus of claim 18, wherein the first side surface further comprises an edge portion formed with a curvature, and the second, opposite side surface further comprises an edge portion formed with a curvature such that when the conductive susceptor is positioned in the reaction zone in the bore of the cylindrical process chamber, the edge portion of the first side surface and the edge portion of the second side surface are complimentarily in contact with and supported by corresponding parts of the inner surface of the body portion of the cylindrical process chamber, respectively.

21. The apparatus of claim 17, wherein the body portion of the conductive susceptor is formed with at least one groove proximate to the bottom surface for facilitating fluid communication inside the bore.

22. The apparatus of claim 1, wherein the longitudinal length L_{I} of the reaction zone and the longitudinal length Lₛ of the conductive susceptor satisfy the following relationship:
Lₛ<L_{I}.

23. The apparatus of claim 1, wherein in operation the induced current penetrates into the conductive susceptor a distance δ satisfying the following relationship:
δ=(2/ωμσ)^{1/2}
wherein ω is the angular frequency of the electromagnetic field, σ is the conductivity of the conductive susceptor, and μ is the absolute magnetic permeability of the conductive susceptor.

24. The apparatus of claim 23, wherein in operation the induced current in the conductive susceptor generates the heat flow by absorbing the energy, P, from the electromagnetic field satisfying the following relationship:
P=Hₒ² 2π(ωμ/σ)^{1/2}
with Hₒ being an amplitude of the electromagnetic field.

25. A nanostructures growth apparatus, comprising:
a. a process chamber having a body portion defining a bore therein;
b. a conductive inductor; and
c. a conductive susceptor with a supporting surface for supporting catalysts and positioned in the bore of the process chamber,
wherein the conductive inductor is configured and positioned in relation to the process chamber such that, in operation, the conductive inductor allows an alternating current to pass through to generate an electromagnetic field with a frequency at least in a reaction zone in the bore and induce current in the conductive susceptor so as to generate a heat flow from the conductive susceptor to the body portion of the process chamber.

26. The apparatus of claim 25, wherein the process chamber is made of a substantially non-conductive material.

27. The apparatus of claim 26, wherein the substantially non-conductive material comprises glass.

28. The apparatus of claim 25, wherein the process chamber is substantially made of quartz.

29. The apparatus of claim 25, wherein the conductive inductor is made from at least one of metals, alloys, and conducting polymeric materials.

30. The apparatus of claim 25, wherein the conductive inductor is in the form of coils surrounding the body portion of the process chamber defining a reaction zone in the bore with a longitudinal length L_{I}.

31. The apparatus of claim 30, wherein the conductive inductor is substantially made from copper.

32. The apparatus of claim 30, wherein the conductive inductor comprises a tube defining a channel therein for circulating a coolant.

33. The apparatus of claim 25, wherein the conductive susceptor is made of a substantially conductive material.

34. The apparatus of claim 33, wherein the conductive susceptor is made of a substantially conductive material that is chemically compatible to carbon and its compounds.

35. The apparatus of claim 34, wherein the substantially conductive material that is chemically compatible to carbon and its compounds comprises graphite.

36. The apparatus of claim 33, wherein the substantially conductive material comprises at least one of metals, alloys, and ferromagnetic materials.

37. The apparatus of claim 25, wherein the conductive susceptor is formed with a bottom surface, a first side surface, a second, opposite side surface, a first end portion, an opposite, second end portion, and a body portion defined therebetween, and wherein the body portion defines a recess.

38. The apparatus of claim 37, wherein the body portion of the conductive susceptor is formed such that when the conductive susceptor is positioned in the reaction zone in the bore of the process chamber, there is at least one space formed between the conductive susceptor and the inner surface of the body portion of the process chamber for facilitating fluid communication inside the bore.

39. The apparatus of claim 25, wherein in operation the induced current penetrates into the conductive susceptor a distance δ satisfying the following relationship:
δ=(2/ωμσ)^{1/2}
wherein ω is the angular frequency of the electromagnetic field, σ is the conductivity of the conductive susceptor, and μ is the absolute magnetic permeability of the conductive susceptor.

40. The apparatus of claim 39, wherein in operation the induced current in the conductive susceptor generates the heat flow by absorbing the energy, P, from the electromagnetic field satisfying the following relationship:
P=Hₒ² 2π(ωμ/σ)^{1/2}
wherein Hₒ is the amplitude of the electromagnetic field.

41. A nanostructures growth apparatus, comprising:
a. a process chamber having a body portion defining a bore therein;
b. an electromagnetic field generating member; and
c. a conductive susceptor with a supporting surface for supporting catalysts and positioned in the bore of the process chamber,
wherein, in operation, the electromagnetic field generating member generates a time-dependent electromagnetic field in the bore and induces current in the conductive susceptor so as to generate a heat flow from the conductive susceptor to the body portion of the process chamber.

42. The apparatus of claim 41, wherein the electromagnetic field generating member comprises a conductive inductor that is made from at least one of metals, alloys, and conducting polymeric materials.

43. The apparatus of claim 42, wherein the conductive inductor is in the form of coils surrounding the body portion of the process chamber defining a reaction zone in the bore with a longitudinal length L_{I} to allow an alternating current to pass through to generate a time-dependent electromagnetic field with a frequency.

44. The apparatus of claim 43, wherein the conductive inductor is substantially made from copper.

45. The apparatus of claim 44, wherein the conductive inductor comprises a tube defining a channel therein for circulating a coolant.

46. The apparatus of claim 41, wherein the electromagnetic field generating member comprises an electromagnetic field generator.

47. The apparatus of claim 41, wherein the conductive susceptor is made of a substantially conductive material.

48. The apparatus of claim 47, wherein the conductive susceptor is made of a substantially conductive material that is chemically compatible to carbon and its compounds.

49. The apparatus of claim 41, wherein in operation the induced current penetrates into the conductive susceptor a distance δ satisfying the following relationship:
δ=(2/ωμσ)^{1/2}
wherein ω is the angular frequency of the time-dependent electromagnetic field, σ is the conductivity of the conductive susceptor, and μ is the absolute magnetic permeability of the conductive susceptor.

50. The apparatus of claim 49, wherein in operation the induced current in the conductive susceptor generates the heat flow by absorbing the energy, P, from the time-dependent electromagnetic field satisfying the following relationship:
P=Hₒ²2π(ωμ/σ)^{1/2}
wherein Hₒ is amplitude of the time-dependent electromagnetic field.

51. A method for making nanostructures, comprising the steps of:
a. placing a conductive susceptor with catalysts in a reaction zone;
b. providing a time-dependent electromagnetic field in the reaction zone so as to induce a current in the conductive susceptor to generate a heat flow;
and
c. supplying a carbon-containing gas to the reaction zone under a set of conditions to interact with the catalysts to allow nanostructures to be formed.

52. The method of claim 51, further comprising the step of purging at least the reaction zone of a nanostructure reactor with an inert gas.

53. The method of claim 51, further comprising the steps of (a) removing the conductive susceptor from the reaction zone and (b) harvesting the nanostructures.

54. The method of claim 51, wherein the time-dependent electromagnetic field has a frequency and amplitude, further comprising the step of adjusting at least one of the frequency and the amplitude of the time-dependent electromagnetic field to control the temperature of the reaction zone.

55. The method of claim 51, wherein the catalysts comprises metallic particles.

56. The method of claim 55, wherein the metal particles are selected from the group consisting of Fe, Ni, Co, and combinations thereof.

57. The method of claim 51, further comprising the step of forming the carbon-containing gas from a carbon source and a carrier gas.

58. The method of claim 57, wherein the carbon source is selected from the group consisting of (a) aromatic hydrocarbons, including benzene, toluene, xylene, cumene, ethylbenzene, naphthalene, phenanthrene, anthracene or mixtures thereof; (b) non-aromatic hydrocarbons, including methane, ethane, ethylene, propane, propylene, acetylene or mixtures thereof; and (c) oxygen-containing hydrocarbons, including formaldehyde, acetaldehyde, acetone, methanol, ethanol or mixtures thereof, and combinations thereof.

59. The method of claim 57, wherein the carrier gas comprises one of Ar gas, hydrogen gas, Ne gas, He gas, or any combination of them.

60. The method of claim 51, wherein the conductive susceptor is made of a substantially conductive material that is chemically compatible to carbon and its compounds.

61. The method of claim 60, wherein the substantially conductive material that is chemically compatible to carbon and its compounds is graphite.

62. The method of claim 51, wherein the conductive susceptor is made of a substantially conductive material.

63. The method of claim 51, wherein the nanostructures as formed comprise nanotubes.

64. The method of claim 51, wherein the nanostructures as formed comprise nanofibers.

65. An apparatus for making nanostructures, comprising:
a. a process chamber having a reaction zone;
b. a conductive susceptor with catalysts placed in the reaction zone;
c. means for providing a time-dependent electromagnetic field in the reaction zone so as to induce a current in the conductive susceptor to generate a heat flow; and
d. means for supplying a carbon-containing gas to the reaction zone under a set of conditions to interact with the catalysts to allow nanostructures to be formed.

66. The apparatus of claim 65, wherein the time-dependent electromagnetic field has a frequency and amplitude, further comprising means for adjusting at least one of the frequency and the amplitude of the time-dependent electromagnetic field to control the temperature of the reaction zone of a nanostructure reactor.

67. The apparatus of claim 65, further comprising means for forming the carbon-containing gas from a carbon source and a carrier gas.

68. A method for making nanostructures, comprising the steps of:
a. placing a conductive susceptor with catalysts in a reaction zone;
b. causing skin effect at least in the conductive susceptor so as to generate a heat flow; and
c. supplying a carbon-containing gas to the reaction zone under a set of conditions to interact with the catalysts to allow nanostructures to be formed.

69. The method of claim 68, further comprising the step of purging at least the reaction zone with an inert gas.

70. The method of claim 68, further comprising the steps of (a) removing the conductive susceptor from the reaction zone and (b) harvesting the nanostructures.

71. The method of claim 68, wherein the causing step further comprises the step of causing skin effect in the catalysts to facilitate the growth of nanostructures.

72. The method of claim 68, wherein the causing step further comprises the step of providing a time-dependent electromagnetic field in the reaction zone so as to causing skin effect.

73. The method of claim 72, wherein an induced current penetrates into the conductive susceptor a distance δ due to the skin effect satisfying the following relationship:
δ=(2/ωμσ)^{1/2}
wherein ω is the angular frequency of the time-dependent electromagnetic field, σ is the conductivity of the conductive susceptor, and μ is the absolute magnetic permeability of the conductive susceptor.

74. The method of claim 73, wherein the induced current in the conductive susceptor generates the heat flow by absorbing the energy, P, from the time-dependent electromagnetic field satisfying the following relationship:
P=Hₒ²2π(ωμ/σ)^{1/2}
wherein Hₒ is amplitude of the time-dependent electromagnetic field.

75. An apparatus for making nanostructures, comprising:
a. a process chamber having a reaction zone;
b. a conductive susceptor with catalysts placed in the reaction zone;
c. means for causing skin effect at least in the conductive susceptor so as to generate a heat flow; and
d. means for supplying a carbon-containing gas to the reaction zone under a set of conditions to interact with the catalysts to allow nanostructures to be formed.

76. The apparatus of claim 75, wherein the causing means comprises means for providing a time-dependent electromagnetic field in the reaction zone so as to cause skin effect.

77. The apparatus of claim 76, wherein an induced current penetrates into the conductive susceptor a distance δ due to the skin effect satisfying the following relationship:
δ=(2/ωμσ)^{1/2}
wherein ω is the angular frequency of the time-dependent electromagnetic field, σ is the conductivity of the conductive susceptor, and μ is the absolute magnetic permeability of the conductive susceptor.

78. The apparatus of claim 77, wherein the induced current in the conductive susceptor generates the heat flow by absorbing the energy, P, from the time-dependent electromagnetic field satisfying the following relationship:
P=Hₒ²2π(ωμ/σ)^{1/2}
wherein Hₒ is amplitude of the time-dependent electromagnetic field.
